(19) United States
(12) Patent Application Publication
(10) Pub. No.: US 2026/0064011 A1
(43) Pub. Date: Mar. 5, 2026

(54) OPTICAL APPARATUS AND METHOD FOR CONTROLLING OPTICAL APPARATUS

(71) Applicant: Lasertec Corporation, Yokohama (JP)

(72) Inventor: Akira UEDA, Yokohama-shi (JP)

(21) Appl. No.: 19/319,317

(22) Filed: Sep. 4, 2025

(30) Foreign Application Priority Data
Sep. 4, 2024 (JP) 2024-152409

(51) Int. Cl. G03F 7/00

(52) U.S. Cl. CPC G03F 7/70508; G03F 7/70141; G03F 7/70358; G03F 7/70525; G03F 7/7085

(57) ABSTRACT

An optical apparatus or the like including a gain changing unit that changes a predetermined gain is provided. An optical apparatus according to the present disclosure includes: a first detection unit configured to detect light coming from an object illuminated by light emitted from a light source and output signals in association with a plurality of positions; a second detection unit configured to detect a part of the light emitted from the light source and output signals in association with a plurality of positions; a signal correction unit configured to correct the signals from the first detection unit based on predetermined gain values determined in advance for the respective positions; and a gain changing unit configured to change the predetermined gain values based on the signals from the second detection unit.

### INCORPORATION BY REFERENCE

This application is based upon and claims the benefit of priority from Japanese patent application No. 2024-152409, filed on Sep. 4, 2024, the disclosure of which is incorporated herein in its entirety by reference for all purposes.

### BACKGROUND

The present disclosure relates to an optical apparatus and a method for correcting an optical apparatus.

There has been a technology for detecting a defect in a sample based on a signal obtained by monitoring illumination.
[Patent Literature 1] Japanese Patent No. 6249513

### SUMMARY

It should be noted that it is possible to control an apparatus more finely based on a result output from an illumination monitor. Therefore, an object of the present disclosure is to provide an optical apparatus or the like including a gain changing unit that changes a predetermined gain.

An optical apparatus according to the present disclosure includes:
a first detection unit configured to detect light coming from an object illuminated by light emitted from a light source and output signals in association with a plurality of positions;
a second detection unit configured to detect a part of the light emitted from the light source and output signals in association with a plurality of positions;
a signal correction unit configured to correct the signals from the first detection unit based on predetermined gains determined in advance for the respective positions; and
a gain changing unit configured to change gains to be used as the predetermined gains based on the signals from the second detection unit, in which
in a predetermined period after an evaluation value based on the signals at the plurality of positions of the second detection unit changes to an evaluation value different from a first evaluation value, when the number of times of acquisition of an evaluation value that differs from the first evaluation value by an amount larger than a first threshold exceeds a second threshold, the gain changing unit changes the predetermined gain, and
the signal correction unit corrects the signal from the first detection unit based on the predetermined gain changed by the gain changing unit.

The optical apparatus according to the present disclosure may further include a drive unit configured to change relative positions of an illumination spot and the object with respect to a stripe on the object, in which
when an evaluation value based on the signals at the plurality of positions of the second detection unit during illumination of a first stripe changes to a evaluation value that differs from the first evaluation value by an amount larger than a third threshold larger than the first threshold, the optical apparatus may control the drive unit so as to perform the illumination of the first stripe again.

The optical apparatus according to the present disclosure may further include a drive unit configured to change relative positions of an illumination spot and the object with respect to a stripe on the object, in which
in a predetermined period after an evaluation value based on the signals at the plurality of positions of the second detection unit obtained during the illumination of the first stripe changes to an evaluation value different from the first evaluation value, when the number of times of acquisition of an evaluation value that differs from the first evaluation value by an amount larger than the first threshold exceeds a fourth threshold larger than the second threshold, the optical apparatus may control the drive unit so as to perform the illumination of the first stripe again.

The optical apparatus according to the present disclosure may adjust an optical element in addition to changing the predetermined gain.

In the optical apparatus according to the present disclosure, the object may be critically illuminated by the light emitted from the light source.

In the optical apparatus according to the present disclosure, the first detection unit and the second detection unit may be arranged at conjugate positions.

In the optical apparatus according to the present disclosure, the gain changing unit may change the predetermined gain based on a result of illumination of a specific region on the object.

A method for controlling an optical apparatus according to the present disclosure is a method for controlling an optical apparatus,
the optical apparatus including:
a first detection unit configured to detect light coming from an object illuminated by light emitted from a light source and output signals in association with a plurality of positions;
a second detection unit configured to detect a part of the light emitted from the light source and output signals in association with a plurality of positions;
a signal correction unit configured to correct the signals from the first detection unit based on predetermined gains determined in advance for the respective positions; and
a gain changing unit configured to change gains to be used as the predetermined gains based on the signals from the second detection unit, in which
in a predetermined period after an evaluation value based on the signals at the plurality of positions of the second detection unit changes to an evaluation value different from a first evaluation value, when the number of times of acquisition of an evaluation value that differs from the first evaluation value by an amount larger than a first threshold exceeds a second threshold, the gain changing unit changes the predetermined gain, and
the signal correction unit corrects the signal from the first detection unit based on the predetermined gain changed by the gain changing unit.

In the method for controlling the optical apparatus according to the present disclosure,
the optical apparatus may further include a drive unit configured to change relative positions of an illumination spot and the object with respect to a stripe on the object, and
when an evaluation value based on the signals at the plurality of positions of the second detection unit during illumination of a first stripe changes to a evaluation value that differs from the first evaluation value by an amount larger than a third threshold larger than the first threshold, the optical apparatus may control the drive unit so as to perform the illumination of the first stripe again.

In the method for controlling the optical apparatus according to the present disclosure,
the optical apparatus may further include a drive unit configured to change relative positions of an illumination spot and the object with respect to a stripe on the object, in which
in a predetermined period after an evaluation value based on the signals at the plurality of positions of the second detection unit obtained during the illumination of the first stripe changes to an evaluation value different from the first evaluation value, when the number of times of acquisition of an evaluation value that differs from the first evaluation value by an amount larger than the first threshold exceeds a fourth threshold larger than the second threshold, the optical apparatus may control the drive unit so as to perform the illumination of the first stripe again.

In the method for controlling the optical apparatus according to the present disclosure, the optical apparatus may adjust an optical element in addition to changing the predetermined gain.

In the method for controlling the optical apparatus according to the present disclosure, the object may be critically illuminated by the light emitted from the light source.

In the method for controlling the optical apparatus according to the present disclosure, the first detection unit and the second detection unit may be arranged at conjugate positions.

In the method for controlling the optical apparatus according to the present disclosure, the gain changing unit may change the predetermined gain based on a result of illumination of a specific region on the object.

According to the present disclosure, an optical apparatus or the like including a gain changing unit that changes a predetermined gain is provided.

The above and other objects, features, and advantages according to the present disclosure will become more fully understood from the detailed description given hereinbelow and the accompanying drawings.

### BRIEF DESCRIPTION OF DRAWINGS

FIG. 1 shows an optical system of an optical apparatus according to an embodiment;

FIG. 2 shows an example of a correction made by a gain according to an embodiment;

FIG. 3 is a block diagram showing a configuration of an optical apparatus according to an embodiment;

FIG. 4 shows profiles of correction scanning according to an embodiment;

FIG. 5 shows Flowchart 1 showing a method for controlling an optical apparatus according to an embodiment;

FIG. 6 shows Flowchart 2 showing a method for controlling an optical apparatus according to an embodiment; and

FIG. 7 shows an optical system of an optical apparatus according to a modified example.

### DESCRIPTION OF EMBODIMENTS

### Embodiments

Embodiments according to the present disclosure will be described hereinafter with reference to the drawings. However, the disclosure according to the claims is not limited to the below-shown embodiments. Further, all of the components/structures described in the embodiments are not necessarily indispensable as means for solving the problem. For clarification of the explanation, the following descriptions and drawings are omitted and simplified as appropriate. The same reference numerals (or symbols) are assigned to the same elements throughout the drawings, and redundant descriptions thereof are omitted as appropriate.

### (Description of Optical Apparatus According to Embodiment)

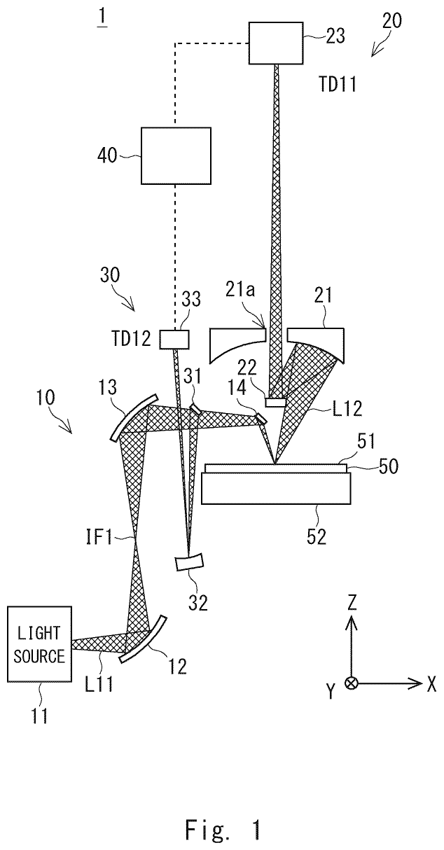

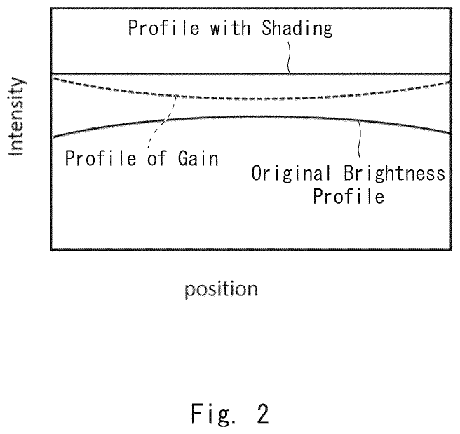

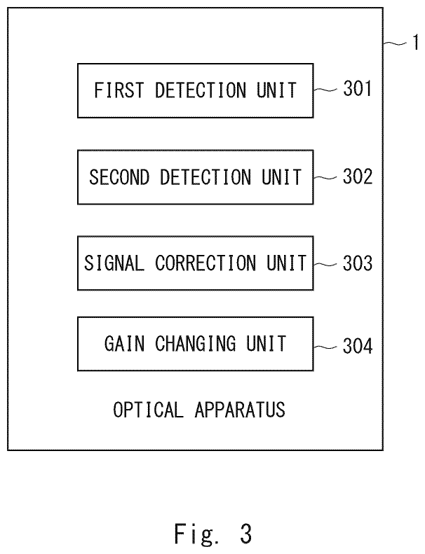

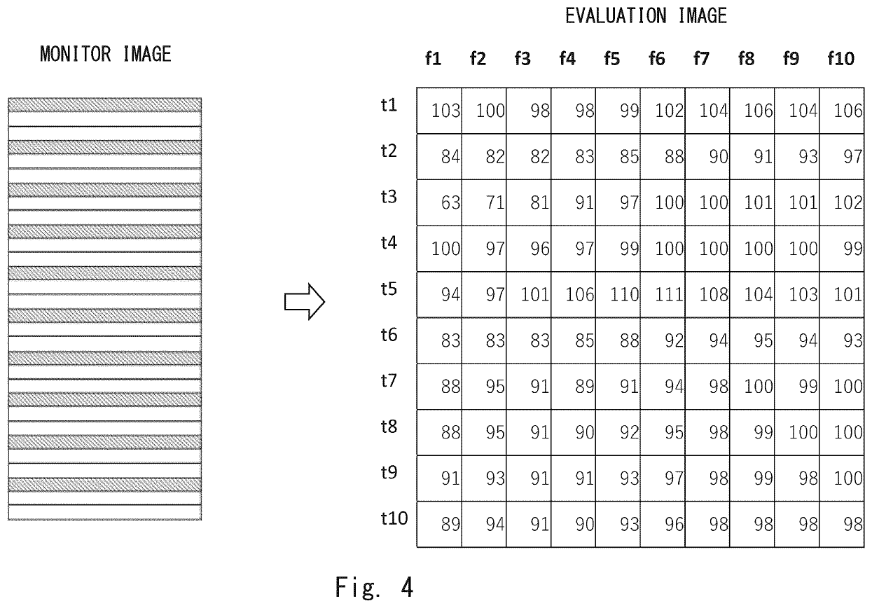

FIG. 1 shows an optical system of an optical apparatus according to an embodiment. FIG. 2 shows an example of a correction made by a gain according to the embodiment. FIG. 3 is a block diagram showing the configuration of the optical apparatus according to the embodiment. FIG. 4 shows profiles of correction scanning according to the embodiment. The optical apparatus according to the embodiment will be described with reference to FIGS. 1 to 4. The optical apparatus is an apparatus for inspecting an object to be inspected for its defect or the like.

As shown in FIG. 1, the optical apparatus according to the embodiment includes an illumination optical system 10, a detection optical system 20, a monitoring unit 30, and a processing unit 40. The illumination optical system 10 includes a light source 11, an elliptical mirror 12, an elliptical mirror 13, and a drop mirror 14. The detection optical system 20 includes a concave mirror 21 with a hole formed therein (hereinafter also referred to as the holed concave mirror 21), a convex mirror 22, and a first detector 23. The holed concave mirror 21 and the convex mirror 22 form a Schwarzschild magnification optical system. The monitoring unit 30 includes a cut mirror 31, a concave mirror 32, and a second detector 33. The object to be inspected is, for example, an EUV mask 50. Note that the object to be inspected is not limited to the EUV mask 50.

The light source 11 generates illumination light L11. The illumination light L11 contains, for example, EUV light having a wavelength of 13.5 nm, which is the same wavelength as an exposure wavelength for the EUV mask 50, i.e., for the object to be inspected. The illumination light L11 generated by the light source 11 is reflected on the ellipsoidal mirror 12. The illumination light L11 reflected on the ellipsoidal mirror 12 travels while becoming narrower (i.e., while its cross section is becoming smaller) and is concentrated at a focal point IF1. The focal point IF1 is positioned in a place conjugate with an upper surface 51 of the EUV mask 50.

After passing through the focal point IF1, the illumination light L11 travels while spreading (i.e., while its cross section is becoming larger) and is incident on a reflecting mirror such as the ellipsoidal mirror 13. The illumination light L11 incident on the ellipsoidal mirror 13 is reflected thereon and travels while becoming narrower. Then, the narrowed illumination light L11 is incident on the dropping mirror 14. That is, the ellipsoidal mirror 13 converges the illumination light L11 and makes the converged light incident on the dropping mirror 14. The dropping mirror 14 is disposed right above the EUV mask 50. The illumination light L11, which has been incident on the dropping mirror 14 and reflected thereon, is incident on the EUV mask 50. That is, the dropping mirror 14 makes the illumination light L11 incident on the EUV mask 50.

The ellipsoidal mirror 13 concentrates the illumination light L11 onto the EUV mask 50. The illumination optical system 10 is configured so that when the illumination light L11 illuminates the EUV mask 50, an image of the light source 11 is formed on the upper surface 51 of the EUV mask 50. Therefore, the illumination optical system 10 provides critical illumination. In this way, the illumination optical system 10 illuminates the object to be inspected by using the critical illumination provided by the illumination light L11 generated by the light source 11.

The EUV mask 50 is disposed on a stage 52. Note that a plane parallel to the upper surface 51 of the EUV mask 50 is defined as an XY-plane and a direction perpendicular to the XY plane is defined as a Z-direction. The illumination light L11 enters (i.e., incident on) the EUV mask 50 in a direction inclined from the Z-direction. That is, the illumination light L11 is obliquely incident on the EUV mask 50 and illuminates the EUV mask 50.

The stage 52 is an XYZ-drive stage. By moving the stage 52 in XY-directions, a desired area on the EUV mask 50 is illuminated. Further, a focus can be adjusted by moving the stage 52 in the Z-direction.

The illumination light L11 emitted from the light source 11 illuminates an inspection area on the EUV mask 50. The inspection area illuminated by the illumination light L11 is, for example, an area of 0.5 mm square. Reflected light L12, i.e., the light that has been incident on the EUV mask 50 in the direction inclined from the Z-direction and reflected thereon, is incident on the holed concave mirror 21. A hole 21a is formed at the center of the holed concave mirror 21.

The reflected light L12 reflected on the holed concave mirror 21 is incident on the convex mirror 22. The convex mirror 22 reflects the reflected light L12 coming from the holed concave mirror 21 toward the hole 21a of the holed concave mirror 21. The reflected light L12, which has passed through the hole 21a, is detected by the first detector 23. The first detector 23 is a detector including a TDI (Time Delay Integration) sensor and acquires image data of the object to be inspected, i.e., the EUV mask 50. The first detector 23 includes a plurality of image pickup elements arranged in a line in one direction. Image data taken by the plurality of image pickup elements arranged in a line is referred to as one-dimensional image data or one frame. The first detector 23 acquires a plurality of one-dimensional image data by performing scanning in a direction perpendicular to the one direction. The image pickup element is, for example, a CCD (Charge Coupled Device). Note that the image pickup element is not limited to the CCD.

As described above, the detection optical system 20 concentrates the reflected light L12 from the object to be inspected illuminated by the illumination light L11 and acquires image data of the EUV mask 50 by detecting the concentrated reflected light L12 by the first detector 23. The image data is, for example, one-dimensional image data.

The reflected light L12 contains information on a defect on the EUV mask 50 and the like. Specular reflection light of the illumination light L11, which has been incident on the EUV mask 50 in the direction inclined from the Z-direction, is detected by the detection optical system 20. When there is a defect on the EUV mask 50, the defect is observed as a dark image. Such an observation method is called a bright-field observation. The plurality of one-dimensional image data of the EUV mask 50 acquired by the first detector 23 are output to the processing unit 40 and processed into two-dimensional image data by the processing unit 40.

As shown in FIG. 1, the cut mirror 31 of the monitoring unit 30 is disposed between the elliptical mirror 13 and the drop mirror 14, and takes out a part of the illumination light L11 between the elliptical mirror 13 and the drop mirror 14. The cut mirror 31 reflects a small part of the beam of the illumination light L11 so that the small part is cut out from the illumination light L11. The part of the beam is, for example, an upper part of the beam.

In a cross-sectional area of a cross section of the illumination light L11 perpendicular to an optical axis 15 thereof at a place where the cut mirror 31 is disposed, a cross-sectional area of the part of the illumination light L11 reflected by the cut mirror 31 is smaller than that of the remaining part of the illumination light L11.

For example, when the cross-sectional area of the cross section perpendicular to the optical axis 15 of the illumination light L11 at the place where the cut mirror 31 is disposed is 100, the cross-sectional area of the taken-out part is about 1. The angle for taking out the part of the illumination light L11 which is taken out from the light source 11 in the direction perpendicular to the optical axis 15 is, for example, ±7°. The angle of the illumination light L11 used for the EUV mask 50 is, for example, in the range of ±6°. Only the upper part of the beam of the illumination light L11 in the range of, for example, 1° is taken out by the cut mirror 31 in order to use it in the monitor unit 30. Even when the upper part of the beam is slightly taken out as described above, the amount of the illumination light L11 incident on the EUV mask 50 barely decreases. Therefore, it is possible to minimize the deterioration of the accuracy of the inspection.

The cut mirror 31 is disposed in, for example, a place close to a pupil in the illumination optical system 10. By taking out the part of the illumination light L11 by the cut mirror 31 in the place close to the pupil in the illumination optical system 10, it is possible to obtain an excellent correlation between image data acquired by the first detector 23 and image data acquired by the second detector 33. Even when an NA (Numerical Aperture) for the first detector 23 differs from an NA for the second detector 33 and hence their PSFs (Point Spread Functions) differ from each other, the difference between the NAs has no adverse effect in this embodiment because the plasma size is sufficiently larger than the PSF size.

The illumination light L11, which has been reflected on the cut mirror 31, travels while being narrowed, and is concentrated at a focal point. After that, the illumination light L11 travels while spreading and is incident on the concave mirror 32.

The concave mirror 32 and a plurality of mirrors (not shown) enlarge the part of the illumination light L11 taken out by the cut mirror 31. Image data acquired by the second detector 33 can be magnified. For example, a magnification of 500 times can be obtained by using a plurality of mirrors.

In this embodiment, a magnification of image data of a brightness distribution acquired by the monitor unit 30 is equal to that of image data of an object to be inspected acquired by the detection optical system 20. Note that the magnification of image data of the brightness distribution acquired by the monitoring unit 30 may be made lower than the magnification of image data of the object to be inspected acquired by the detection optical system 20. A solid angle necessary for taking out a part of the light is equivalent to the square of the magnification ratio. For example, when the magnification of the first detector 23 is 20 times and the magnification of the second detector 33 is 2 times, the solid angle necessary for taking out the part of the light by using the cut mirror 31 is one hundredth ( 1/100) of the solid angle for taking out the light emitted from the light source 11. When expressed by the NA, it is one tenth ( 1/10).

The illumination light L11, which has been incident on the concave mirror 32 and reflected thereon, is detected by the second detector 33. The second detector 33 is a detector including a TDI (Time Delay Integration) sensor and acquires image data of a brightness distribution of the illumination light L11. The second detector 33 includes a plurality of image pickup elements arranged in a line in one direction. Similarly to the first detector 23, image data taken by the plurality of image pickup elements arranged in a line is referred to as one-dimensional image data or one frame. The second detector 33 acquires a plurality of one-dimensional image data by performing scanning in a direction perpendicular to the one direction. The one-dimensional image data acquired by the second detector 33 indicates variations in the power (hereinafter referred to as power variations) of the illumination light L11 and a brightness distribution thereof. The image pickup element is, for example, a CCD (Charge Coupled Device). Note that the image pickup element is not limited to the CCD.

For example, the optical system is configured so that an image of the light source 11 for the illumination light L11 is formed on the second detector 33. In this way, the monitoring unit 30 acquires image data that makes it possible to identify power fluctuations and/or a brightness distribution of the illumination light L11 that is detected by irradiating the second detector 33 with critical illumination by using the part of the illumination light L11 (hereinafter this image data is also referred to as “image data of power fluctuations and brightness distribution” or “monitor image”). Therefore, it is possible to accurately correct the brightness distribution and the power variations.

The first detector 23 and the second detector 33 have a conjugate relationship therebetween.

As described above, the monitoring unit 30 concentrates the part of the illumination light L11 and acquires image data of the power variations and the brightness distribution of the illumination light L11 by detecting the concentrated illumination light L11 by the second detector 33. The image data of the power variations and the brightness distribution of the illumination light L11 acquired by the second detector 33 is output to the processing unit 40.

The processor 40 is connected to the detection optical system 20 and the monitoring unit 30 through signal lines or wirelessly. The processing unit 40 receives image data of the object to be inspected from the first detector 23 of the detection optical system 20. Further, the processing unit 40 receives image data of the power variations and the brightness distribution of the illumination light L11 from the second detector 33 of the monitor unit 30.

The processing unit 40 corrects the image data of the EUV mask 50 acquired by the detection optical system 20 based on the image data of the power variations and the brightness distribution acquired by the monitoring unit 30. In addition, the processor 40 inspects the EUV mask 50 based on the corrected image data of the EUV mask 50. Because the optical apparatus 1 inspects the object to be inspected based on corrected image data of the object to be inspected, the optical apparatus 1 can be regarded as an optical apparatus equipped with a correction apparatus.

The processing unit 40 performs a Shading correction for correcting the brightness distribution of the illumination light L11 detected by the first detector 23.

The shading correction will be briefly described with reference to FIG. 2. It is assumed that the original brightness Profile detected by the first detector 23 has an upward convex shape. For this original brightness profile, the processing unit 40 (signal correction unit) performs a shading correction by applying a gain having a Profile having a downward convex shape to the original brightness Profile (by applying a gain defined by a set of gain values having a downward-convex shape profile). As a result, the shading-corrected Profile has a flat shape. By obtaining a Profile having a flat shape, it is possible to, for example, perform a defect inspection of the object based on the difference between the brightness of a certain pixel(s) and the brightness of a pixel(s) adjacent thereto with higher accuracy.

Note that the gain is a predetermined gain that is set in advance so as to have a specific shape according to the characteristics and the like of the first detector 23 and/or the illumination light L11. Note that the shape of the predetermined gain shown in FIG. 2 is merely an example, and the shape of the predetermined gain may be a shape other than this shape as long as it is possible to correct the Profile to one having an arbitrary shape (e.g., a flatter shape) by the shading correction. In the present disclosure, the gain may be defined by a plurality of gain values applied to the respective positions, and the set of such gain values collectively constitutes the predetermined gain.

It should be noted that in the inspection using critical illumination, the state of the light source (bright spot) significantly affects the fluctuations of the brightness distribution in the first detector 23. This is because, for example, when the light source (bright spot) moves in the plane direction perpendicular to the optical axis, the position where the brightness Profile has the upward convex shape in the first detector 23 (i.e., the vertex position) moves in the left-right direction.

Patent Literature 1 proposes a method for solving such a problem, that is, an apparatus and method for a shading correction in which the fluctuations of the brightness distribution in the first detector 23 are taken into consideration, and the processing unit 40 according to this embodiment performs a shading correction in which the fluctuations of the brightness distribution in the first detector 23 are taken into consideration by a method similar to the apparatus and method disclosed in Patent Literature 1.

That is, the processing unit 40 determines how to apply a predetermined gain to the brightness Profile acquired by the first detector 23 based on the brightness Profile acquired by the second detector 33. As an example, the processing unit 40 performs a shading correction for the first detector 23 based on the gain obtained by moving the predetermined gain by +x1 in the X axis direction based on the result of a determination that the position of the vertex of the brightness Profile acquired by the second detector 33 has moved by +x1 in the +X axis direction relative to the position of the vertex of the reference brightness Profile. Alternatively, as another example, the processing unit 40 performs a shading correction for the first detector 23 based on the gain obtained by lowering the predetermined gain by −ΔI based on the result of a determination that the Intensity at the position of the vertex of the brightness Profile acquired by the second detector 33 is larger than the Intensity at the position of the vertex of the reference brightness Profile by ΔI. Note that although the position of the vertex of the brightness Profile of the second detector 33 is used as the comparison reference position, the comparison reference position is not limited to this example. That is, an arbitrary point may be used as the comparison reference position. Further, the movement of the predetermined gain in the X axis direction or the movement thereof in the Intensity direction may be applied over the whole predetermined gain, or may be applied to a part of the predetermined gain such as a visual field position (position on the X axis) at which the fluctuation is particularly large.

As shown in FIG. 3, the optical apparatus 1 according to the embodiment includes a first detection unit 301, a second detection unit 302, and a processing unit 40 including a signal correction unit 303 and a gain changing unit 304.

The first detection unit 301 corresponds to a first detector TDI 1. The first detection unit 301 detects light coming from the object irradiated with light emitted from the light source. The first detection unit 301 outputs optical signals in association with a plurality of positions. The plurality of positions means that detection units arranged in one dimension are associated with detectors.

The second detection unit 302 corresponds to a second detector TDI 2. The second detection unit 302 detects a part of light emitted from the light source. The second detection unit 302 outputs optical signals in association with a plurality of positions. The plurality of positions means that detection units arranged in one dimension are associated with detectors.

The signal correction unit 303 corrects the signals from the first detection unit 301 based on predetermined gains determined in advance for the respective positions. The signal correction unit 303 corrects the signals from the first detection unit 301 based on the predetermined gains. For example, the corrected signals have values represented by the Profile with Shading shown in FIG. 2. As described above, the correcting based on the predetermined gain may include correcting the predetermined gain to a gain that is obtained by moving the predetermined gain in the X axis direction for at least a part of the visual field position of the predetermined gain, and correcting the predetermined gain to a gain that is obtained by moving the predetermined gain in the Intensity direction for at least a part of the visual field position of the predetermined gain.

Note that when the predetermined gain has already been changed by the gain changing unit as will be described later, the signal correction unit 303 corrects the signals from the first detection unit 301 based on the changed predetermined gain.

### (Control Upon Fluctuation)

The processing unit 40 performs control upon fluctuation (i.e., control that is performed when a fluctuation occurs) in order to cope with a state change which cannot be coped with by the signal correction based on the predetermined gain by the signal correction unit 303 described above, that is, in order to achieve finer apparatus control. The control upon fluctuation includes, as will be described later, rewriting of the gain to be used as the predetermined gain by the gain changing unit 304, rescanning through the drive control of a stage 52, or other optical adjustments.

The gain changing unit 304 changes the predetermined gain based on the signals from the second detection unit 302, that is, based on the result of the evaluation of an evaluation image (which will be described later). The change of the predetermined gain is merely an example of the control upon fluctuation.

The processing unit 40 performs rescanning based on the signals from the second detection unit 302, that is, based on the result of the evaluation of an evaluation image (which will be described later). The rescanning is merely an example of the control upon fluctuation. The processing unit 40 may perform an optical adjustment, instead of or in addition to the change of the predetermined gain or the rescanning, based on the signals from the second detection unit 302, that is, based on the result of the evaluation of an evaluation image (which will be described later). The processing unit 40 may perform rescanning or an optical adjustment in addition to the change of the predetermined gain.

### (Evaluation Image)

An evaluation image will be described with reference to FIG. 4. The left part of FIG. 4 is a part of a monitor image that is acquired based on signals from the second detection unit 302 when an inspection image of a certain stripe is acquired. Note that the stripes are an area virtually set on the object to be inspected, and may mean, for example, an image area on the object to be inspected that is obtained based on signals of the first detection unit 301 by, under the assumption that the direction in which the sensors are arranged in a line is the X axis direction, relatively moving the object to be inspected from one end to the other end in the Y axis direction while maintaining the position in the X-direction fixed. Further, the inspection image of a certain stripe may mean an image of the object to be inspected that is obtained based on the first detection unit 301 when the object to be inspected is relatively moved in the Y axis direction with respect to one arbitrary stripe among a plurality of stripes present on the object to be inspected.

When the inspection image of a certain stripe is acquired by the second detection unit 302 having the above-described configuration, a monitor image is acquired based on signals of the second detection unit 302. As an example, the vertical direction of the monitor image shown in the left part of FIG. 4 corresponds to the time (when the second detection unit 302 is a TDI, it can also be regarded as the scanning position), and the horizontal direction corresponds to the direction in which the sensors are arranged in a line.

An image obtained by taking out at least a part of the monitor image is called an evaluation image, and an example thereof is shown in the right part of FIG. 4. The evaluation image is an image for evaluating whether or not a power fluctuation or a change in the brightness distribution at a predetermined level has occurred based on signals from the second detection unit 302 acquired at a certain time, or based on the average or the sum of signals from the second detection unit 302 acquired at a plurality of consecutive times.

As an example, as shown in the right part of FIG. 4, the evaluation image may be obtained by dividing outputs of sensors of the second detection unit 302, which are arranged in a line, obtained for respective control times into 10 sections (f1 to f10) and arranging them in order of the control time (t1 to t10). Under the assumption that, for example, 40 sensors are arranged in a line, for each of the sections f1 to f10, the value of the section may be obtained by summing up the outputs of the four sensors belonging to that section. Note that the evaluation image may be obtained by, instead of arranging signals of respective control times in a chronological order, taking out signals at certain intervals among a plurality of control times and arranging them in a chronological order, or averaging the outputs of the second detection unit 302 for respective control times at a plurality of consecutive control times (e.g., four consecutive control times) and arranging them in order of the control time. The right part of FIG. 4 shows an example of an evaluation image in which the outputs of the second detection unit 302 for every third control times indicated by hatched lines in the monitor image shown in left part of Fi. 4 are arranged for 10 control times in association with f1 to f10.

Although the evaluation image is generated from a part of the monitor image in the above example for the sake of explanation, how to generate an evaluation image is not limited to this example. That is, an evaluation image may be directly generated based on the second detection unit 302. Further, since the evaluation image may be data containing information that can be used for image generation, it is referred to as the evaluation image in the above description. However, the evaluation image does not have to be displayed on a display unit or the like so that the user can recognize it as an image. In this case, the evaluation image may be referred to as evaluation data as appropriate.

### (Evaluation Value Used for Determining Necessity of Control Upon Fluctuation)

The processing unit 40 uses an intensity value and/or uniformity calculated based on the above-described evaluation image as an evaluation value used for determining the necessity of control upon fluctuation.

The intensity value as an example of such an evaluation value can be obtained by, for example, the below-shown expression.

(Average−Shading Target)/Shading Target

For example, at a time t1, the average is expressed as (103+100+98+98+99+102+104+106+104+106)/10=102. Here, assuming that the shading target is 100, the intensity value at the time t1 is 0.02.

The uniformity as an example of an evaluation value can be obtained by, for example, the below-shown expression.

(Maximum Value−Minimum Value)/(Maximum Value+Minimum Value)

For example, the maximum value is 106 and the minimum value is 98 at the time t1, so that the uniformity at the time t1 is expressed as 8/204=0.039216.

### (Determination of Necessity of Control Upon Fluctuation)

### (Part 1, Gain Rewriting Process)

The processing unit 40 (gain changing unit 304) performs the below-shown gain rewriting when it is determined that a fluctuation in the evaluation value in a relatively small value range has occurred a plurality of times within a predetermined period.

That is, in a predetermined period after an evaluation value based on signals at a plurality of positions of the second detection unit 302 changes to an evaluation value different from a first evaluation value, when the number of times of acquisition of an evaluation value that differs from the first evaluation value by an amount larger than a first threshold exceeds a second threshold, the gain changing unit changes the predetermined gain. Changing the predetermined gain includes changing the values at the respective visual field positions (positions on the X axis) of the gain to be used as the predetermined gain to values different from the original values and/or changing the shape of the gain (i.e., the gain curve) to be used as the predetermined gain to a shape different from the original shape. The predetermined period may be, as an example, a period in which the same stripe as that in which the change of the evaluation value to an evaluation value different from the first evaluation value has been detected is being inspected. The first evaluation value is a reference value, and may be, for example, 0.0 for the intensity value and 0.0 for the uniformity. Note that the fact that the difference from the first evaluation value is larger than the predetermined threshold may mean that the absolute value of the difference between the first evaluation value and the acquired evaluation value is larger than the predetermined threshold.

The processing unit 40 (gain changing unit 304) changes the gain to be used as the predetermined gain, and the signal correction unit 303 corrects signals based on the changed predetermined gain as described above. In this way, the signal correction unit 303 can appropriately cope with a state change that cannot be sufficiently coped with by correcting signals based on the original predetermined gain (which includes correcting the original predetermined gain to a gain that is obtained by moving the original predetermined gain in the X axis direction for at least a part of the visual field position of the original predetermined gain, and/or correcting the original predetermined gain to a gain that is obtained by moving the original predetermined gain in the Intensity direction for at least a part of the visual field position of the original predetermined gain).

### (Part 2, Rescanning Process)

The processing unit 40 performs a rescanning process when it is determined that a fluctuation in the evaluation value in a relatively large value range has occurred. The rescanning is a process for acquiring, for the stripe of which an inspection image is to be acquired, an inspection image again from the beginning by controlling the drive unit as will be described later.

That is, when it is determined that a difference between the evaluation value based on the signals at the plurality of positions of the second detection unit 302 and the first evaluation value is larger than a third threshold during the acquisition of an inspection image of a predetermined stripe, the processing unit 40 drives the stage 52 and acquires an inspection image of the predetermined stripe again.

The first evaluation value is a reference value, and may be, for example, 0.0 for the intensity value and 0.0 for the uniformity. The same value as the reference value used for the determination of the gain rewriting process may be used as the reference value used for the determination of the rescanning process. Alternatively, a value (second evaluation value) different from the value of the reference value used for the determination of the gain rewriting process (i.e., the first evaluation value) may be used as the reference value used for the determination of the rescanning process. Note that the fact that the difference from the first evaluation value is larger than the predetermined threshold may mean that the absolute value of the difference between the first evaluation value and the acquired evaluation value is larger than the predetermined threshold. The third threshold (threshold for the absolute value of the difference from the first evaluation value used for the determination of the rescanning process) is larger than the first threshold (threshold for the absolute value of the difference from the first evaluation value used for the determination of the gain change). In this case, the same value as the reference value used for the above-described determination of the gain rewriting process may be used as the reference value used for the determination of the rescanning process.

Note that in a predetermined period after an evaluation value based on the signals at the plurality of positions of the second detection unit 302 obtained during the illumination of the predetermined stripe changes to an evaluation value different from the first evaluation value, when the number of times of acquisition of an evaluation value that differs from the first evaluation value by an amount larger than the first threshold exceeds a fourth threshold, the processing unit 40 may drive the stage 52 so as to perform the illumination of the first stripe again. The second threshold and the fourth threshold are predetermined number of times, and may be different from each other, and expressed as Fourth Threshold>Second Threshold.

The stage 52 is a drive unit that moves in the XYZ directions. The stage 52 changes the relative positions of the illumination spot, which is a focal point, and the object. For example, when one stripe is to be obtained along the Y axis, the stage is driven in the Y axis direction in order to continuously apply the illumination spot to the same stripe (i.e., to the one stripe).

The processing unit 40 may adjust an optical element in addition to changing the predetermined gain. The adjustment of the optical element may be automatic or manual, but it is preferably an automatic adjustment of a range.

The gain changing unit 304 may determine the changed predetermined gain based on the result of the illumination of a specific region on the object. The gain changing unit 304 may determine the changed predetermined gain, for example, based on the result of the illumination of a reference region on the object where there is no defect.

By the above-described configuration, an optical apparatus or the like including a gain changing unit that changes a predetermined gain is provided.

### (Description of Method for Collecting Optical Apparatus According to Embodiment)

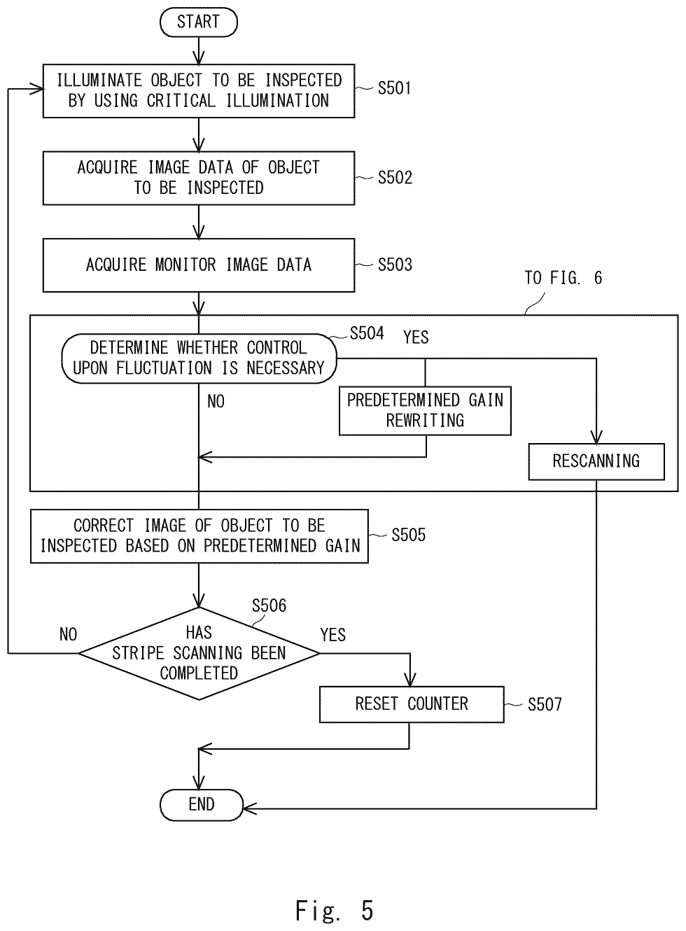

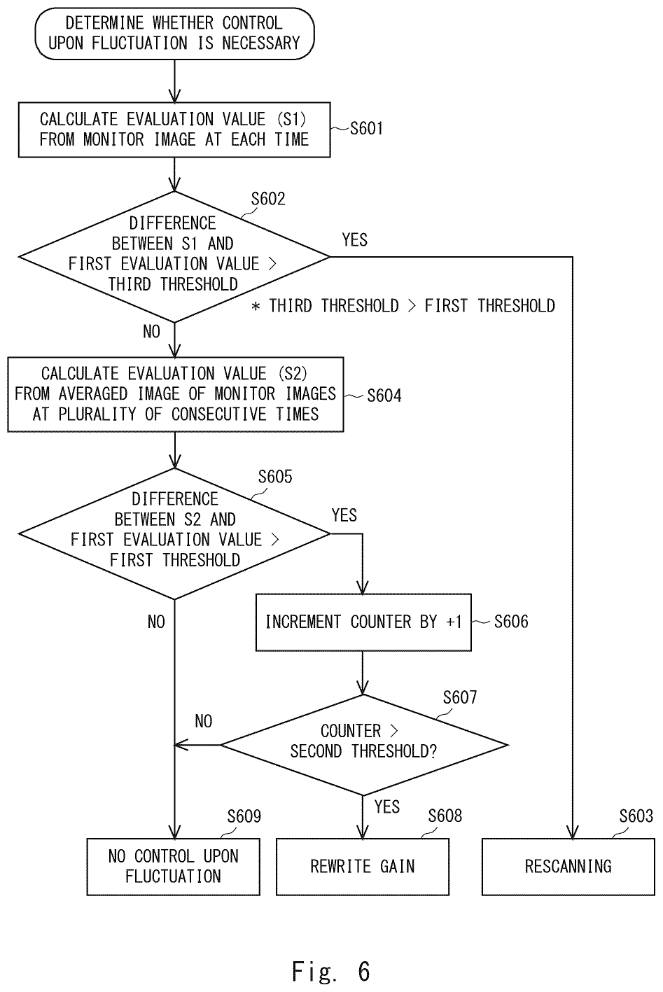

FIG. 5 shows Flowchart 1 showing a method for controlling an optical apparatus according to an embodiment. FIG. 6 shows Flowchart 2 showing a method for controlling an optical apparatus according to an embodiment. A method for controlling an optical apparatus according to the embodiment will be described with reference to FIGS. 5 and 6.

As shown in FIG. 5, the object to be inspected is first illuminated by using critical illumination (Step S501). Next, image data of the object to be inspected is acquired (Step S502). The image data of the object to be inspected is acquired by the first detector TDI 1. Next, monitor image data is acquired (Step S503). The monitor image data is acquired by the second detector TDI 2. Next, it is determined whether or not it is necessary to perform control upon fluctuation (Step S504).

When it is necessary to perform control upon fluctuation (Yes in Step S504), the predetermined gain is rewritten, or rescanning is performed, or an optical adjustment is made. The rewriting of the predetermined gain or the rescanning will be described later with reference to FIG. 6. In the case of the rewriting of the predetermined gain, the process proceeds to a step S505. In the case of the rescanning, the series of processes are finished. Thereafter, the rescanning is executed, and in the rescanning process Steps S501 to S507 may be performed in the same manner.

When it is not necessary to perform control upon fluctuation (No in Step S504), the image data of the object to be inspected is corrected based on the predetermined gain (Step S505). Next, it is determined whether or not the scanning of the stripe has been completed (Step S506). When the scanning of the stripe has been completed (Yes in Step S506), the counter is reset (e.g., initialized) and the series of processes are finished (Step S507). The counter will be described later. When the scanning of the stripe has not been completed yet, the process returns to the step S501.

Control upon fluctuation will be described with reference to FIG. 6. When it is determined whether or not it is necessary to perform at least one of various types of control upon fluctuation, an evaluation value (S1) is calculated, for example, from monitor image data at respective times (Step S601). An evaluation value is calculated from the image data of the second detector TDI 2. Next, it is determined whether or not a difference between the evaluation value S1 and the first evaluation value is larger than the third threshold (Step S602). It is determined whether or not the difference between the evaluation value S1 and the first evaluation value is larger than the third threshold, i.e., has significantly changed. When the difference is larger than the third threshold (Yes in Step S602), rescanning is performed (Step S603).

When the difference between the evaluation value S1 and the first evaluation value is not larger than the third threshold (No in Step S602), an evaluation value (S2) is calculated from an averaged image of the monitor image data at a plurality of consecutive times (Step S604). Next, it is determined whether or not a difference between the evaluation value S2 and the first evaluation value is larger than the first threshold (Step S605). When the difference between the evaluation value S2 and the first evaluation value is not larger than the first threshold (No in Step S5605), the process proceeds to the step S505 without performing control upon fluctuation. When the difference between the evaluation value S2 and the first evaluation value is larger than the first threshold (Yes in Step S605), the counter is incremented (Step S606). It is determined whether or not the value of the counter is larger than a threshold for the number of times (Step S607). When the value of the counter is larger than the threshold for the number of times (Yes in Step S607), the predetermined gain is rewritten and the process proceeds to the step S505 (Step S608). When the value of the counter is not larger than the threshold for the number of times (No in Step S607), the process proceeds to the step S505 without performing control upon fluctuation.

By the above-described configuration, a method for controlling an optical apparatus including a gain changing unit that changes a predetermined gain is provided. Note that although the rescanning is performed in the step S603, when a predetermined condition is satisfied, the rewriting of the gain may be performed in addition to the rescanning. The predetermined condition may be, for example, a condition that rescanning is performed a plurality of times in the same stripe, or a condition that rescanning is performed again before a predetermined time elapses from the last rescanning. In this way, it is possible to prevent the rescanning from being repeatedly performed.

### (Application of Control Method to Modified Example of Optical Apparatus)

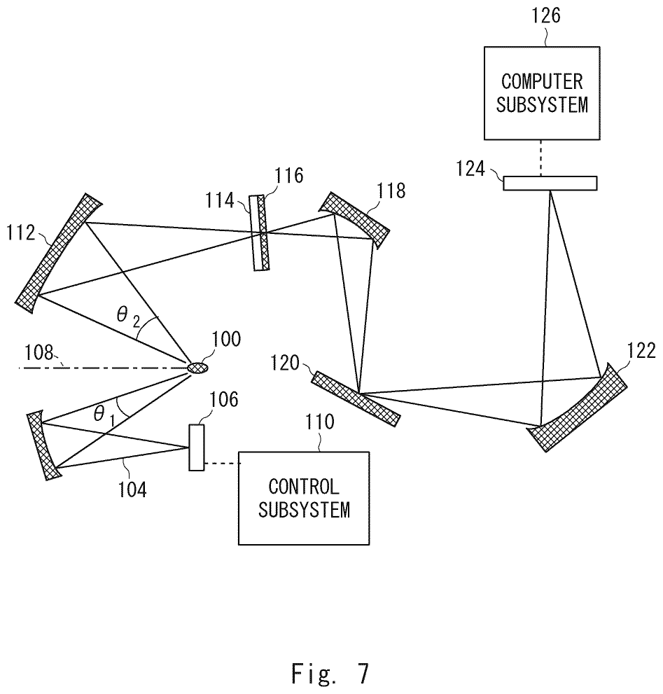

FIG. 7 is a modified example of an optical apparatus. Light emitted from a light source 100 is applied to an object 116 and detected by a first detection unit 124. Further, a part of the light emitted from the light source is applied to a second detection unit 106 and is thereby detected. The light detected by the second detection unit 106 is used for the correction of light detected by the first detection unit.

A control method according to the present disclosure can also be applied to such an optical system. That is, control upon fluctuation is performed based on light detected by the second detection unit 106. The control upon fluctuation may include a gain rewriting process, rescanning, and an optical adjustment. A processing unit (a signal correction unit and a gain changing unit) is included in a control subsystem 110 and a computer subsystem 126.

Then, in a predetermined period after an evaluation value based on the signals at the plurality of positions of the second detection unit 106 changes to an evaluation value different from the first evaluation value, when the number of times of acquisition of an evaluation value that differs from the first evaluation value by an amount larger than the first threshold exceeds the second threshold, the predetermined gain is changed (predetermined gain rewriting process) The signal correction unit corrects signals from the first detection unit based on the predetermined gain changed by the gain changing unit.

The processing unit 40 is physically configured at least by a processor (for example, a central processing unit (CPU)) that executes a program for executing processing and a memory that stores the program.

In addition, a part or all of the processing in the processing unit 40 described above can be enabled as a computer program. Such a program can be stored and supplied to the computer using various types of non-transitory computer-readable media. The non-transitory computer-readable media include various types of tangible recording media. Examples of the non-transitory computer-readable media include a magnetic recording medium (e.g., a flexible disk, a magnetic tape, or a hard disk drive), a magneto-optical recording medium (e.g., a magneto-optical disc), a CD-read only memory (ROM), a CD-R, a CD-R/W, and a semiconductor memory (e.g., a mask ROM, a programmable ROM (PROM), an erasable PROM (EPROM), a flash ROM, or a random access memory (RAM)). The program may be supplied to the computer using various types of transitory computer-readable media. Examples of the transitory computer-readable media include electrical signals, optical signals, and electromagnetic waves. The transitory computer-readable media can supply the programs to the computer via a wired communication path such as an electric wire and an optical fiber or a wireless communication path.

Note that the present disclosure is not limited to the above-described embodiments, and they may be modified as appropriate without departing from the scope and spirit of the disclosure. The following configuration is also encompassed by the technical thought of the embodiments.

### (Supplementary Note 1)

An optical apparatus comprising:
a first detector configured to detect light coming from an object illuminated by light emitted from a light source and output signals in association with a plurality of positions;
a second detector configured to detect a part of the light emitted from the light source and output signals in association with a plurality of positions;
a processor; and
a memory storing instructions which, when executed by the processor, cause the processor to:
correct the signals from the first detector based on predetermined gain values determined in advance for the respective positions; and
change gain values to be used as the predetermined gain values based on the signals from the second detector;
wherein, in a predetermined period after an evaluation value based on the signals at the plurality of positions of the second detector changes to an evaluation value different from a first evaluation value, when the number of times of acquisition of an evaluation value that differs from the first evaluation value by an amount larger than a first threshold exceeds a second threshold, the processor changes the predetermined gain values, and
the processor corrects the signals from the first detector based on the predetermined gain values changed by the processor.

What is claimed is:

1. An optical apparatus comprising:
a first detection unit configured to detect light coming from an object illuminated by light emitted from a light source and output signals in association with a plurality of positions;
a second detection unit configured to detect a part of the light emitted from the light source and output signals in association with a plurality of positions;
a signal correction unit configured to correct the signals from the first detection unit based on predetermined gain values determined in advance for the respective positions; and
a gain changing unit configured to change gain values to be used as the predetermined gain values based on the signals from the second detection unit, wherein
in a predetermined period after an evaluation value based on the signals at the plurality of positions of the second detection unit changes to an evaluation value different from a first evaluation value, when the number of times of acquisition of an evaluation value that differs from the first evaluation value by an amount larger than a first threshold exceeds a second threshold, the gain changing unit changes the predetermined gain values, and
the signal correction unit corrects the signals from the first detection unit based on the predetermined gain values changed by the gain changing unit.

2. The optical apparatus according to claim 1, further comprising a drive unit configured to change relative positions of an illumination spot and the object with respect to a stripe on the object, wherein
when an evaluation value based on the signals at the plurality of positions of the second detection unit during illumination of a first stripe changes to an evaluation value that differs from the first evaluation value by an amount larger than a third threshold larger than the first threshold, the optical apparatus controls the drive unit so as to perform the illumination of the first stripe again.

3. The optical apparatus according to claim 1, further comprising a drive unit configured to change relative positions of an illumination spot and the object with respect to a stripe on the object, wherein
in a predetermined period after an evaluation value based on the signals at the plurality of positions of the second detection unit obtained during the illumination of the first stripe changes to an evaluation value different from the first evaluation value, when the number of times of acquisition of an evaluation value that differs from the first evaluation value by an amount larger than the first threshold exceeds a fourth threshold larger than the second threshold, the optical apparatus controls the drive unit so as to perform the illumination of the first stripe again.

4. The optical apparatus according to claim 1, wherein the optical apparatus adjusts an optical element in addition to changing the predetermined gain values.

5. The optical apparatus according to claim 1, wherein the object is critically illuminated by light emitted from the light source.

6. The optical apparatus according to claim 1, wherein the first detection unit and the second detection unit are arranged at conjugate positions.

7. The optical apparatus according to claim 1, wherein the gain changing unit changes the predetermined gain values based on a result of illumination of a specific region on the object.

8. A method for controlling an optical apparatus,
the optical apparatus comprising:
a first detection unit configured to detect light coming from an object illuminated by light emitted from a light source and output signals in association with a plurality of positions;
a second detection unit configured to detect a part of the light emitted from the light source and output signals in association with a plurality of positions;
a signal correction unit configured to correct the signals from the first detection unit based on predetermined gain values determined in advance for the respective positions; and
a gain changing unit configured to change gain values to be used as the predetermined gain values based on the signals from the second detection unit, wherein
in a predetermined period after an evaluation value based on the signals at the plurality of positions of the second detection unit changes to an evaluation value different from a first evaluation value, when the number of times of acquisition of an evaluation value that differs from the first evaluation value by an amount larger than a first threshold exceeds a second threshold, the gain changing unit changes the predetermined gain values, and
the signal correction unit corrects the signal from the first detection unit based on the predetermined gain values changed by the gain changing unit.

9. The method for controlling an optical apparatus according to claim 8, wherein
the optical apparatus further includes a drive unit configured to change relative positions of an illumination spot and the object with respect to a stripe on the object, and
when an evaluation value based on the signals at the plurality of positions of the second detection unit during illumination of a first stripe changes to an evaluation value that differs from the first evaluation value by an amount larger than a third threshold larger than the first threshold, the optical apparatus controls the drive unit so as to perform the illumination of the first stripe again.

10. The method for controlling an optical apparatus according to claim 8, wherein
the optical apparatus further includes a drive unit configured to change relative positions of an illumination spot and the object with respect to a stripe on the object, and
in a predetermined period after an evaluation value based on the signals at the plurality of positions of the second detection unit obtained during the illumination of the first stripe changes to an evaluation value different from the first evaluation value, when the number of times of acquisition of an evaluation value that differs from the first evaluation value by an amount larger than the first threshold exceeds a fourth threshold larger than the second threshold, the optical apparatus controls the drive unit so as to perform the illumination of the first stripe again.

11. The method for controlling an optical apparatus according to claim 8, wherein the optical apparatus adjusts an optical element in addition to changing the predetermined gain values.

12. The method for controlling an optical apparatus according to claim 8, wherein the object is critically illuminated by the light emitted from the light source.

13. The method for controlling an optical apparatus according to claim 8, wherein the first detection unit and the second detection unit are arranged at conjugate positions.

14. The method for controlling an optical apparatus according to claim 8, wherein the gain changing unit changes the predetermined gain values based on a result of illumination of a specific region on the object.
